(19) United States
(12) Patent Application Publication
(10) Pub. No.: US 2007/0114626 A1
(43) Pub. Date: May 24, 2007

(54) PHOTODIODE DEVICE AND PHOTODIODE ARRAY FOR OPTICAL SENSOR USING THE SAME

(75) Inventors: Shin Jae KANG, KYUNGKI-DO (KR); Won Tae CHOI, KYUNGKI-DO (KR); Joo Yul KO, KYUNGKI-DO (KR); Deuk Hee PARK, SEOUL (KR)

Correspondence Address: LOWE HAUPTMAN BERNER, LLP, 1700 DIAGONAL ROAD, SUITE 300, ALEXANDRIA, VA, 22314, US

(73) Assignee: SAMSUNG ELECTRO-MECHANICS CO., LTD., KYUNGKI-DO (KR)

(21) Appl. No.: 11/533,084

(22) Filed: Sep. 19, 2006

(30) Foreign Application Priority Data
Nov. 24, 2005 (KR) 10-2005-0113029

(51) Int. Cl. H01L 27/14

(52) U.S. Cl. 257/431; 257/E31.028

(57) ABSTRACT

The invention relates a photodiode device and a photodiode array using the same capable of detecting short and long wavelengths of visible light at a high efficiency. The photodiode device includes: a first conductivity type semiconductor substrate; a second conductivity type buried layer, an intrinsic semiconductor layer and a first conductivity type semiconductor layer formed on the semiconductor substrate in their order; and a second conductivity type well layer formed on the first conductivity type semiconductor layer. The second conductivity type buried layer, the intrinsic semiconductor layer and the first conductivity type semiconductor layer form a pin junction diode for detecting the long wavelength of visible light, and the first conductivity type semiconductor layer and the second conductivity type well layer form a p-n junction diode for detecting a short wavelength of light.

### CLAIM OF PRIORITY

This application claims the benefit of Korean Patent Application No. 2005-113029 filed on Nov. 24, 2005, in the Korean Intellectual Property Office, the disclosure of which is incorporated herein by reference.

### BACKGROUND OF THE INVENTION

1. Field of the Invention

The present invention relates to a photodiode device, and more particularly, to a high quality double junction photodiode device and a photodiode array using the same capable of detecting short and long wavelengths of visible light at a high efficiency.

2. Description of the Related Art

According to the development of image communication technologies using high-speed wired and wireless networks and image input and recognition technologies using a digital camera and so on, demands for optical sensors such as an image sensor, a color sensor and a luminance sensor are on the rise. Such an optical sensor has a photodiode for detecting an optical sensor and converting it into an electric signal. The optical sensor typically adopts a p-n junction diode or a pin junction diode.

P-n junction diodes are widely used since they have a simple structure and thus can be easily fabricated by a Complementary Metal Oxide Semiconductor (CMOS) process. However, as pixel size is reduced owing to its high density, the photosensitivity of a photodiode device having a p-n junction is degraded gradually. This as a result has introduced a pin junction diode where a photodetection area (in particular photodetection depth) is increased to improve the photosensitivity of a photodiode device. The photosensitivity of a typical photodiode is proportional to the photodetection area and the vertical photodetection depth.

Recently, there are demands for a photodiode device for an optical sensor capable of selectively or discriminatively detecting several wavelengths in order to obtain a higher photodetection efficiency. By using such a photodiode for an optical sensor having a selective detection function, it is possible to simultaneously detect multiple wavelengths and enhance photosensitivity with respect to the photodetection area.

FIG. 1 is a cross-sectional view schematically illustrating an example of a photodiode device 10 having a p-n junction diode structure of the prior art. Referring to FIG. 1, the photodiode device 10 includes an n-type well layer 13 formed on a p-type silicon (Si) substrate 11. The n-type well layer 13 together with a portion of the p-type substrate 11 forms a p-n junction diode 14. In the vicinity of the p-n junction diode 14, a circuit 19 including metal lines 17 is formed. A transparent dielectric layer 15 is formed on the substrate 11, and a color filter 21 for allowing passage of a specific wavelength of light is formed inside the dielectric layer 15.

When the photodiode device 10 is emitted with light, the p-n junction diode 14 generate an excess carrier in response to the light filtered by the color filter 21. The excess carrier then changes a current or voltage so that the photodiode device 10 outputs an electric signal. However, the p-n junction diode 14 can rarely detect the light at a high efficiency owing to its relatively low photosensitivity. In particular, the p-n junction diode 14 has a low optical efficiency for the long wavelength of visual light (e.g., red and green wavelength lights) having an absorption depth of 6 μm or more since its depletion layer is formed typically at a depth of 1 μm to 3 μm.

FIG. 2 is a cross-sectional view illustrating another example of a photodiode device 20 having a pin junction structure of the prior art. Referring to FIG. 2, the photodiode device 20 includes an intrinsic epitaxial layer 22 and an n-type well layer formed on a p-type Si substrate 11. On the intrinsic epitaxial layer 22, a dielectric layer 25 may be formed. The intrinsic epitaxial layer 22 and the n-type well layer 23 together with a portion of the p-type substrate 11 form a pin junction diode 24. The intrinsic epitaxial layer 22 also referred to as a region i, when formed as above, can increase the thickness of a depletion region in the photodiode and thus the photosensitivity. However, it is impossible to discriminatively detect short and long wavelengths of light at the same time by using a single one of the photodiode device 20.

FIG. 3 is a block diagram illustrating a photodiode array of an optical sensor 50 of the prior art. Referring to FIG. 3, the optical sensor 50 includes a photodiode array 30 for detecting Red (R), Green (G) and Blue (B) light and a Trans-Impedance Amplifier (TIA) 40 for converting a current signal to a voltage signal. To detect R, G and B light discriminatively using the photodiode array 30 of the prior art, at least three photodiode devices are necessary. This as a result increases the space occupied by the photodiode array, and thus acts as an obstruction against high-density pixels and small sized optical sensor devices.

### SUMMARY OF THE INVENTION

The present invention has been made to solve the foregoing problems of the prior art and therefore an object of certain embodiments of the present invention is to provide a photodiode device capable of detecting short and long wavelengths of visible light at a high efficiency.

Another object of certain embodiments of the present invention is to provide a photodiode array capable of detecting individual wavelengths of visible light at a higher efficiency while reducing an occupation area.

According to an aspect of the invention for realizing the object, there is provided a photodiode device. The photodiode device includes: a first conductivity type semiconductor substrate; a second conductivity type buried layer, an intrinsic semiconductor layer and a first conductivity type semiconductor layer formed on the semiconductor substrate in their order; and a second conductivity type well layer formed on the first conductivity type semiconductor layer, wherein the second conductivity type buried layer, the intrinsic semiconductor layer and the first conductivity type semiconductor layer form a pin junction diode for detecting the long wavelength of visible light, and the first conductivity type semiconductor layer and the second conductivity type well layer form a p-n junction diode for detecting a short wavelength of light. Here, the long wavelength of visible light corresponds to green to red wavelengths of visible light, and the short wavelength of light corresponds to a blue wavelength of visible light. (Hereinafter the green wavelength of light will be commonly referred to as “green light”, the red wavelength of light, as “red light,” and the blue wavelength of light, as “blue light.”)

Preferably, the first conductivity type is p-type, and the second conductivity type is n-type. Preferably, each of the first intrinsic semiconductor layer and the first conductivity type semiconductor layer is an epitaxial layer. More preferably, the semiconductor substrate comprises a Si substrate, and the semiconductor layers are made of a Si semiconductor.

According to an embodiment of the invention, the photodiode device may further include a second conductivity type vertical buried region extending through the first conductivity type semiconductor layer and the intrinsic semiconductor layer to the second conductivity type buried layer to provide a contact toward the second buried layer.

Preferably, the second conductivity type well layer has a junction depth ranging from 0.1 μm to 0.2 μm. Preferably, an interface is provided between the first conductivity type semiconductor layer and the intrinsic semiconductor layer at a depth ranging from 1 μm to 1.5 μm. Preferably, an interface is provided between the intrinsic semiconductor layer and the second conductivity type semiconductor layer at a depth ranging from 5 μm to 7 μm. Also preferably, an interface is provided between the second conductivity type buried layer and the semiconductor substrate at a depth ranging from 8 μm to 10 μm.

Preferably, the second conductivity type well layer has a doping concentration ranging from 1×10¹⁹ cm⁻³ to 3×10¹⁹ cm⁻³. Preferably, the first conductivity type semiconductor layer has a doping concentration ranging from 5×10¹⁶ cm⁻³ to 5×10¹⁷ cm⁻³. Preferably, the intrinsic semiconductor layer has a doping concentration ranging from 1×10¹³ cm⁻³ to 1×10¹⁴ cm⁻³. Preferably, the second conductivity type buried layer has a doping concentration ranging from 1×10¹⁸ cm⁻³ to 3×10¹⁸ cm⁻³. Also preferably, the semiconductor substrate has a doping concentration ranging from 1×10¹⁵ cm⁻³ to 1×10¹⁶ cm⁻³.

According to another aspect of the invention for realizing the object, there is provided a photodiode array. The photodiode array includes at least one color filter; and at least two photodiode devices of the invention as described above. With the photodiode array, it is possible to obtain more enhanced photosensitivity and light efficiency according to red, green and blue wavelengths.

According to an embodiment of the invention, the photodiode array includes a first photodetector having a red light filter and a first photodiode device, a second photodetector having a green light filter and a second photodiode device, and a third photodetector having a blue light filter and a third photodiode device. Here, the first to third photodiode devices are those of the invention as described invention.

According to another embodiment of the invention, the photodiode array includes a first photodetector for detecting a green light having a red light filter and a first photodiode device, and a second photodetector for detecting red and blue lights having a second photodiode device without a filter. Here, the first and second photodiode devices are those of the invention as described invention.

According to certain embodiments of the invention, a p-n junction diode for detecting a short wavelength and a pin junction diode for detecting a long wavelength can be integrated in a photodiode device in order to detect short and long wavelengths of visible light discriminatively from each other at a high efficiency. By using the photodiode device, a photodiode array can be realized in a smaller area. This also can reduce the occupation area of the array, thereby leading to high-density pixels and the miniaturization of optical sensor devices such as a color sensor, an image sensor and a luminance sensor.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view schematically illustrating an example of a photodiode device of the prior art;

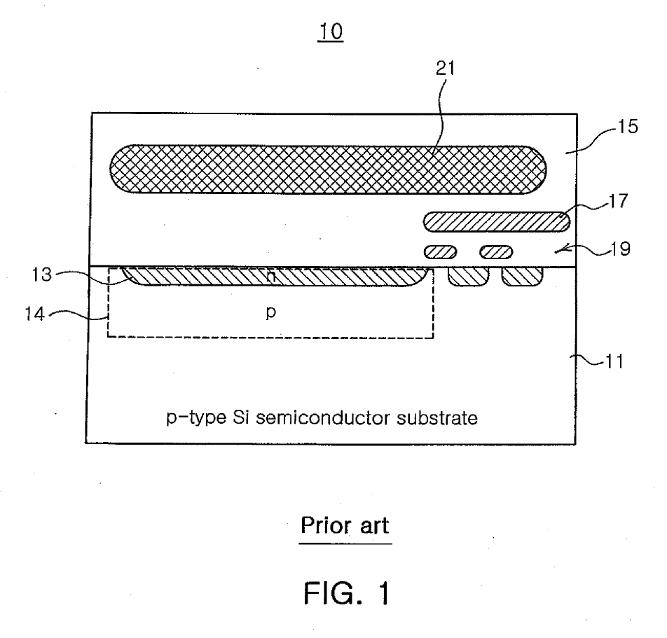

FIG. 2 is a cross-sectional view illustrating another example of a photodiode device of the prior art;

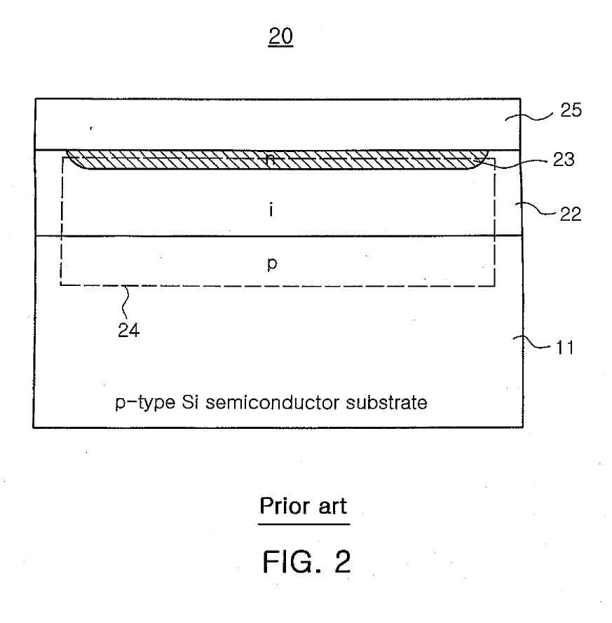

FIG. 3 is a block diagram illustrating a photodiode array of an optical sensor of the prior art;

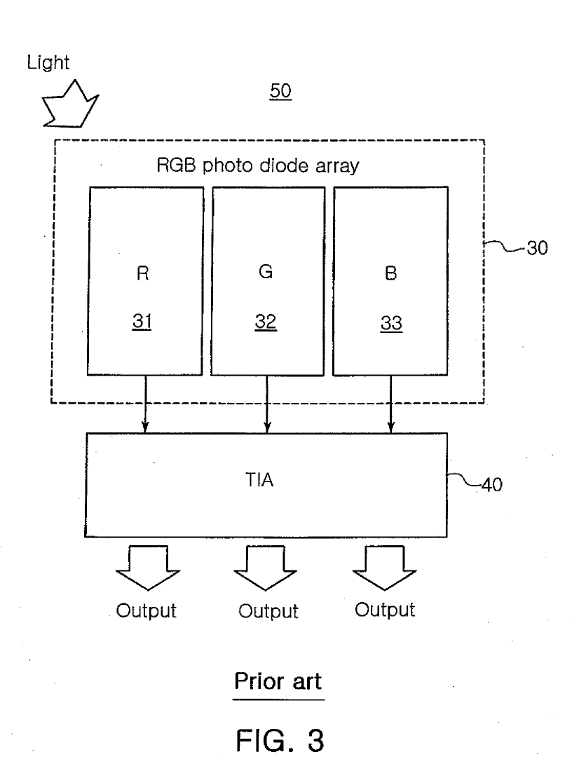

FIG. 4 is a cross-sectional view illustrating a photodiode device according to an embodiment of the invention;

FIG. 5 is a graph illustrating a doping concentration profile according to the depth of the photodiode device of the invention;

FIG. 6 is a graph illustrating an energy band gap of the photodiode device of the invention;

FIG. 7 is a block diagram illustrating a photodiode array of an optical sensor according to an embodiment of the invention; and

FIG. 8 is a block diagram illustrating a photodiode array of an optical sensor according to another embodiment of the invention.

### DETAILED DESCRIPTION OF THE PREFERRED EMBODIMENT

The present invention will now be described more fully hereinafter with reference to the accompanying drawings, in which preferred embodiments of the invention are shown. The invention may however be embodied in many different forms and should not be construed as limited to the embodiments set forth herein. Rather, these embodiments are provided so that this disclosure will be thorough and complete, and will fully convey the scope of the invention to those skilled in the art.

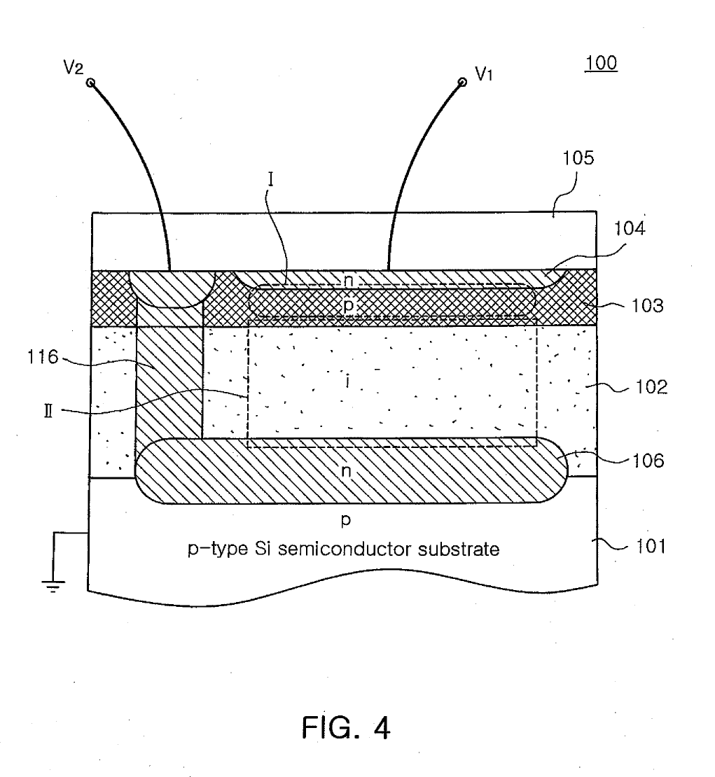

FIG. 4 is a cross-sectional view illustrating a photodiode device 100 according to an embodiment of the invention. The photodiode device 100 corresponds to a Si based semiconductor device. Referring to FIG. 4, the photodiode device 100 includes a p-type Si semiconductor substrate 101, an intrinsic (i-type) epitaxial layer 102 formed on the semiconductor substrate 101 and a p-type epitaxial layer 103 formed on the i-type epitaxial layer 102. Here, the “intrinsic” epitaxial layer 102 is not necessarily limited to the strict definition of an intrinsic semiconductor, but may adopt a semiconductor having a doping concentration up to 10¹⁵ cm⁻³.

An n-type buried layer 106 is sandwiched between the substrate 101 and the intrinsic epitaxial layer 102, and an n-type well layer 104 is formed in an upper central portion of the p-type epitaxial layer 103. In addition, an n-type vertical diffused region 116 is extended through the p-type epitaxial layer 103 and the intrinsic epitaxial layer 102 to the n-type buried layer 106. The n-type vertical diffused region 116 provides a contact toward the n-type buried layer 106.

The n-type buried layer 106, the intrinsic (i-type) epitaxial layer 102 and the p-type epitaxial layer 103 form a pin junction diode. As described later, the pin junction diode is placed in a deep region of a semiconductor substrate to detect the long wavelength of light such as green and red lights. In addition, the p-type epitaxial layer 103 and the n-type well layer forms a p-n junction diode, which is placed in a shallow region of a semiconductor substrate to detect a short wavelength of visible light.

The p-n junction diode composed of the p-type epitaxial layer 103 and the n-type well layer 104 forms a depletion region (see region I in FIG. 4) of a predetermined thickness around a junction interface. Of light incident onto the p-n junction diode, a short wavelength of visible light is mainly absorbed in the region I to generate electron-hole pairs. When generated by the short wavelength of light incident onto the region I like this, electrons and holes move under an electric field, which is formed by a supply voltage externally applied thereto, thereby forming a photo generation current for the short wavelength of visible light. The photo generation current is detected as an electric signal through a terminal V1.

The pin junction diode composed of the n-type buried layer 106, the intrinsic epitaxial layer 102 and p-type epitaxial layer 103 forms a thick depletion region (see region II in. FIG. 4) generally in the intrinsic epitaxial layer 102. Light (in particular, the long wavelength of light such as green and red wavelength lights) incident onto the pin junction diode is generally absorbed in the region II to generate electron-hole pairs. When generated by the long wavelength of light incident onto the region II like this, electrons and holes move under an electric field, which is formed by a supply voltage externally applied thereto, thereby forming a photo generation current for the long wavelength of visible light. The photo generation current is detected as an electric signal through the vertical diffused region 116 and a terminal V2.

With the p-n junction diode formed in the shallow region of the Si substrate and the pin junction diode formed in the deep region of the Si substrate, the photodiode device 100 has a double junction structure. In the double junction structure, the p-n junction diode provides a shallow detection region for the short wavelength of light and the deep pin-junction diode provides a deep detection region for the long wavelength of light as will be describe later.

general, light incident onto a Si semiconductor shows “absorption depth” characteristics varying according to wavelength. That is, a short wavelength of visible light in the vicinity of blue wavelength band (about 460 nm) is absorbed in a shallow region (at a depth of about 1 μm) of the Si substrate, the long wavelength of light in the vicinity of green wavelength band (about 540 nm) is absorbed in a deep region (at a depth of about 3 μm) of the Si substrate, and the long wavelength of light in the vicinity of red wavelength band (about 650 nm) is absorbed in a deeper region (at a depth of about 6 μm or more) of the Si substrate.

By using such absorption depth characteristics, the photodiode 100 shows a high sensitivity for the short wavelength of visible light in the shallow region I (i.e., the depletion region of the p-n junction diode) and a high sensitivity for the long wavelength of visible light in the deep region II (e.g., the depletion region of the pin junction diode). That is, the shallow region I acts as a photo-detection region sensitive to the short wavelength of visible light (blue), whereas the deep region II acts as a photo-detection region sensitive to the long wavelength of visible light (red and green). Accordingly, the photodiode 100 can detect the short wavelength of visible light together with the long wavelength of visible light discriminatively but simultaneously, with a high efficiency.

As shown in FIG. 4, a transparent dielectric layer 105 is formed on the n-type well layer 104. A color filter of organic material (not shown) may be applied optionally on the dielectric layer 105. The color filter allows the passage of specific wavelength light, enabling selective detection of the specific wavelength light (or light signals). For example, a green light filter allows the passage of merely green optical signals so that the photodiode under the filter can detect the green optical signals only.

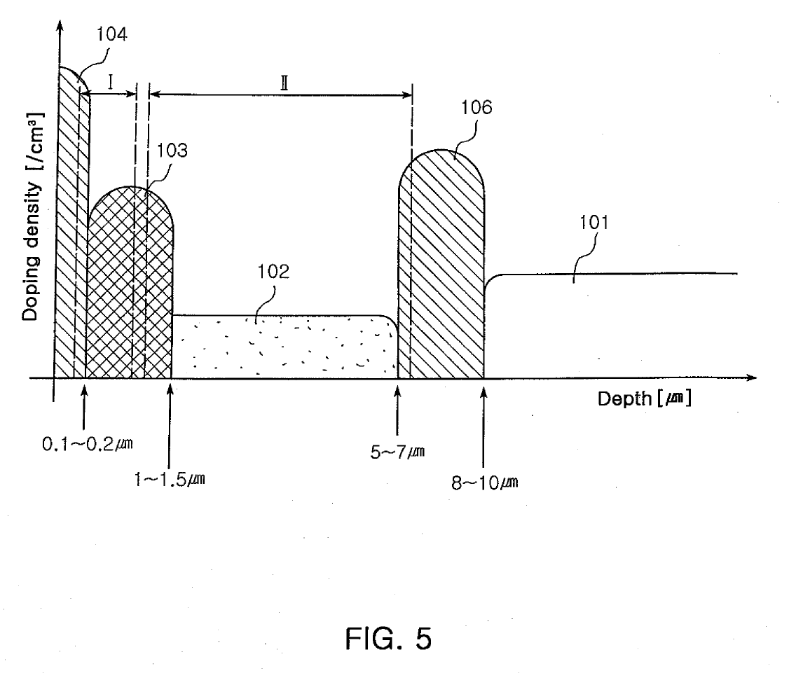

FIG. 5 is a graph illustrating a doping concentration profile according to the depth of the photodiode device 100 of this embodiment. Referring to FIG. 5 together with FIG. 4, the n-type well layer 104 is formed on the p-type epitaxial layer 103 according to a shallow junction ranging from about 0.1 μm to about 0.2 μm. Preferably, the n-type well layer 104 has a doping concentration ranging from about 1×10¹⁹ cm⁻³ to about 3×10¹⁹ cm⁻³. The p-type epitaxial layer 103 is formed at a depth ranging from about 1 μm to 1.5 μm (i.e., the depth of the interface between the p-type epitaxial layer 103 and the intrinsic epitaxial layer 102 ranges from 1 μm to 1.5 μm), and has a doping concentration preferably ranging from 5×10¹⁶ cm⁻³ to 5×10¹⁷ cm⁻³.

Most of the depletion region (region I) of the p-n junction diode composed of the shallow n-type well layer 104 and the p-type epitaxial layer 103 is formed in a portion of the p-type epitaxial layer 103 at a depth of 1.2 μm or less. Since absorption depth for the short wavelength of visible light (blue light) is about 1 μm as described above, the region I functions as an effective detection region for the short wavelength of visible light.

Referring to FIGS. 4 and 5, the intrinsic epitaxial layer 102 is formed at a depth ranging from 5 μm to 7 μm (i.e., the depth of the interface between the intrinsic epitaxial layer 102 and the n-type buried layer 106 ranges from about 5 μm to 7 μm), and has a doping concentration preferably ranging from 1×10¹³ cm⁻³ to 1×10¹⁴ cm⁻³. The intrinsic epitaxially layer 102 may employ any of n- and p-type impurities doped therein. The n-type buried layer 106 is formed at a depth ranging from about 8 μm to 10 μm (i.e., the depth of the interface between the n-type buried layer 106 and the p-type semiconductor substrate 101 ranges from 8 μm to 10 μm), and has a doping concentration preferably ranging from 1×10¹⁸ cm⁻³ to 3×10¹⁸ cm⁻³. Also preferably, the p-type semiconductor substrate 101 has a doping concentration ranging from 1×10¹⁵ cm⁻³ to 1×10¹⁶ cm⁻³.

Most of the depletion region (region II) of the pin junction diode composed of the p-type epitaxial layer 103, the intrinsic epitaxial layer 102 and the n-type buried layer 106 is formed in the region of the intrinsic epitaxial layer 102 at a depth ranging from 1 μm to 7 μm. Since absorption depth for the long wavelength of visible light (red and green light) is about 3 μm to 6 μm as described above, the region II functions as an effective detection region for the long wavelength of visible light.

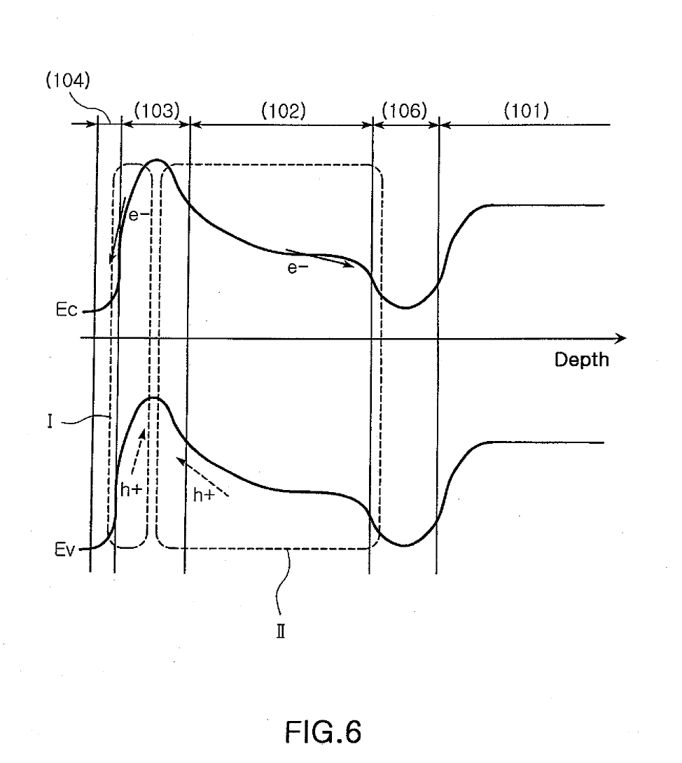

Next, with reference to FIG. 6, description will be given of the concept of electron-hole generation and carrier flows carried out by the photodiode device of the invention. FIG. 6 is a graph illustrating an energy band gap of the photodiode device of the invention. In particular, FIG. 6 shows the energy band gap of the photodiode device and the flow of carriers (electron and hole) therein when the photodiode device is energized. In the energy band diagram shown in FIG. 6, EC indicates the edge of a conduction band, EV indicates the edge of a valance band. In the actuation of the photodiode, a p-n or pin junction diode in the photodiode device is reverse biased as in a common photodiode device.

As shown in FIG. 6, the p-n junction diode composed of the n-type well layer 104 and the p-type epitaxial layer 103 forms a depletion region (area). When a reverse voltage is applied (i.e., when the photodiode device is energized), the region I is formed mostly in the p-type epitaxial layer 103 at a depth of 1.2 μm or less to receive a short wavelength of light. The short wavelength of light absorbed in the region I generates electron-hole pairs, such that electrons (e−) generated cross over the junction and move to the electrode of the n-type well layer 104. Furthermore, holes (h+) generated cross over the junction and move to the p-type epitaxial layer 103. Such a carrier flow generates a short wavelength photo current Iₚₕ_{_{—}}ₛₕₒᵣₜ as in Equation 1 below:
Iₚₕ_{_{—}}ₛₕₒᵣₜ=qA(Lₙ+Wₛₕₒᵣₜ+Lₚ)G_{Lshort} Equation 1,

where q is the magnitude of electronic charge, A is the cross section of the p-n junction diode, Wₛₕₒᵣₜ is the thickness of the depletion region (region I). In addition, Lₙ and Lₚ indicate diffusion lengths of electrons and holes, respectively, and G_{Lshort} indicates the production ratio of electrons/holes with respect to the short wavelength of visible light.

In Equation 1 above, G_{Lshort} has a very small value at a depth of 1 μm or more, it is preferable that Wₛₕₒᵣₜ or the thickness of the depletion region (region I) is limited to 1 μm or less. Therefore, it is preferable that the thickness of the p-type epitaxial layer 103 is limited to 1 μm or less and has a doping concentration ranging from 5×10¹⁶ cm⁻³ to 5×10¹⁷ cm⁻³. Since Wₛₕₒᵣₜ can be reduced according to the junction depth of the n-type well layer 104, the n-type well layer 104 is formed preferably by a shallow junction to minimize the junction depth of the n-type well layer 104.

In addition, as shown in FIG. 6, the pin junction diode composed of the p-type epitaxial layer 103, the intrinsic epitaxial layer 102 and the n-type buried layer 106 forms the depletion region (region II). When a reverse voltage is applied (i.e., the photodiode device is energized), the region II is formed mostly in the intrinsic epitaxial layer 102 at a depth ranging from 1 μm to 7 μm to absorb a long wavelength of visible light including green and red lights. the long wavelength of light absorbed in the region II generates electron-hole pairs, such that electrons (e−) generated cross over the junction and move to the electrode of the n-type buried layer 106, and holes (h+) generated cross over the junction and move to the p-type epitaxial layer 102. Such a carrier flow generates a long wavelength photo current Iₚₕ_{_{—}}_{long} as in Equation 2 below:
Iₚₕ_{_{—}}_{long}=qA′(Lₙ+W_{long}+Lₚ)G_{Llong} Equation 2,

where q is the magnitude of electronic charge, A′ is the cross section of the pin junction diode, W_{long} is the thickness of the depletion region (region II). In addition, Lₙ and Lₚ indicate diffusion lengths of the electrons and holes, respectively, G_{Long} indicates the production ratio of electrons/holes with respect to the long wavelength of visible light. In Equation 2 above, since W_{long} is very large compared with Lₙ and Lₚ, Lₙ and Lₚ are negligible. Therefore, Equation 2 above can be simplified as in Equation 3 below:
Iₚₕ_{_{—}}_{long}=qA′·W_{long}·G_{Llong} Equation 3,

where it can be understood that W_{long} is substantially the same as the thickness of the intrinsic epitaxial layer 102. Therefore, the photo current Iₚₕ_{_{—}}_{long} with respect to the long wavelength of visible light increases in proportion to the thickness of the intrinsic epitaxial layer 102. Where the intrinsic epitaxial layer 102 has a very low doping concentration such as 1×10¹³ cm⁻³, a high production ratio of electrons/holes G_{Llong} can be obtained.

According to this embodiment as described above, a novel structure of photodiode device in the form of “n-p-i-n” is produced from the p-n junction diode and the pin junction diode combined under the p-n junction diode. Unlike conventional photodiode devices, this novel photodiode structure can detect the long wavelength of visible light together with the short wavelength of visible light discriminatively and effectively. Furthermore, in the photodiode device of this embodiment, the p-n junction diode and the pin junction diode can be optimized to control optical efficiency for the short wavelength of visible light and that for the long wavelength of visible light, independently and adequately.

First, the optical efficiency for the short wavelength of visible light can have a suitable value through the optimization of the upper p-n junction diode. Since most of the short wavelength of visible light (blue light) is absorbed at a depth of 1 μm or less, the depletion region of the p-n junction diode is preferably formed in this range of depth. With higher concentration and smaller depth, the n-type well layer 104 may increase optical efficiency for the short wavelength of visible light.

The p-type epitaxial layer 103 acts as a common anode for the upper p-n junction diode and the lower pin Junction diode. Therefore, it is preferable that the p-type epitaxial layer 103 has a doping concentration on the order of 10¹⁷ cm⁻³ considering resistance characteristics of an anode electrode. The p-type epitaxially layer 103 preferably has a thickness on the order of 1 μm for selective detection of the short wavelength of visible light and the long wavelength of visible light. If the p-type epitaxial layer 103 under the n-type epitaxial layer 104 is 2 μm or more, the upper p-n junction diode may absorb the long wavelength of visible light as well as the short wavelength of visible light, and thus may lower selective photodetection characteristics.

Second, the optical efficiency for the long wavelength of visible light may have a suitable value through the optimization of the lower pin junction diode. Since most of the long wavelength of visible light (green and red lights) is absorbed in a depth of 6 μm or less, the intrinsic epitaxial layer 102 forming a light absorbing region of the pin junction diode is preferably arranged in a depth ranging from 1 μm to 7 μm. By suitably selecting the position and thickness of the intrinsic epitaxial layer 102, the optical efficiency for the long wavelength of visible light can be optimized. As a result, it is possible to optimize optical efficiency without any interference between the short wavelength of visible light and the long wavelength of visible light.

The photodiode device according to certain embodiments of the invention can be effectively applied to a photodiode array for detection of red, green and blue lights in an optical sensor such as an image sensor and color sensor.

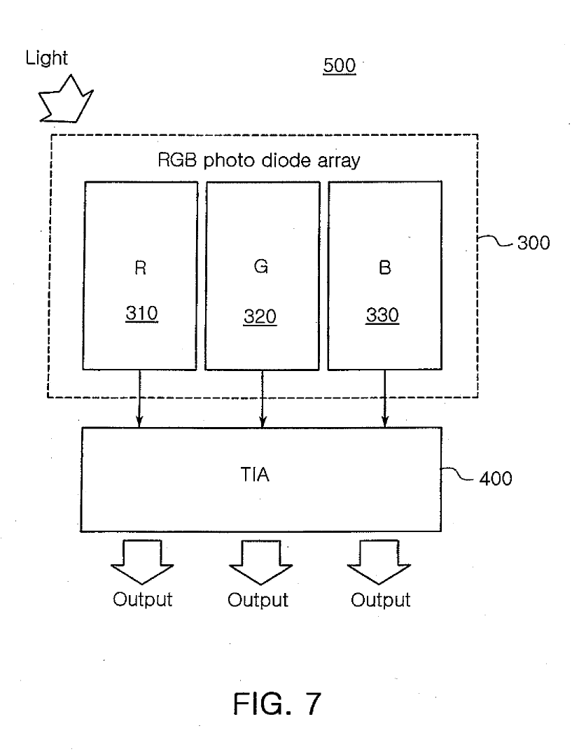

FIG. 7 is a block diagram illustrating a photodiode array of an optical sensor 500 according to an embodiment of the invention, in which the photodiode array includes red, green and blue light filters. Referring to FIG. 7, the optical sensor 500 such as an image sensor or color sensor includes a photodiode array 300 for detecting Red (R), Green (G) and Blue (B) light and a TIA 400 for converting a current signal into a voltage signal. The photodiode array 300 includes at least three photodiode devices (first to third photodiode devices). The first to third photodiode devices have a “n-p-i-n” structure according to the above-stated embodiment.

The photodiode array 300 includes a first photodetector 310 having a red light filter and a first photodiode device, a second photodetector 320 having a green light filter and a second photodiode device and a third photodetector 330 having a blue light filter and a third photodiode device. It is not necessary to apply only one photodiode device to one photodetector 310, 320 or 330, but a plurality of photodiode devices may be applied to the photodetector 310, 320 or 330 to obtain larger output.

Upon having passed through the color filter of the photodetector 310, 320 or 330, specific wavelength light is detected by the photodiode device arranged under the filter. That is, red light after having passed through the red light filter is detected at a high optical efficiency by a deep pin junction diode of the photodiode device (having a “n-p-i-n” structure) in the first photodetector 310. In the same fashion, green light after having passed through the green light filter is detected at a high optical efficiency by a deep pin junction diode of the photodiode device (having a “n-p-i-n” structure) in the second photodetector 320. In addition, blue light after having passed through the blue light filter is detected at a high optical efficiency by a shallow p-n junction diode of the photodiode device in the third photodetector 330.

The individual photodiode device in the photodiode array 300 shows a high optical sensitivity and efficiency for corresponding wavelength owing to the above-stated “n-p-i-n” structure. Therefore, this can enhance the overall optical efficiency and sensitivity of the photodiode array 300, and thus reduce the number of photodiode devices to be equipped in the individual photodetector. Accordingly, it is possible to decrease a space occupied by the entire photodiode array as well as reduce the size of the optical sensor.

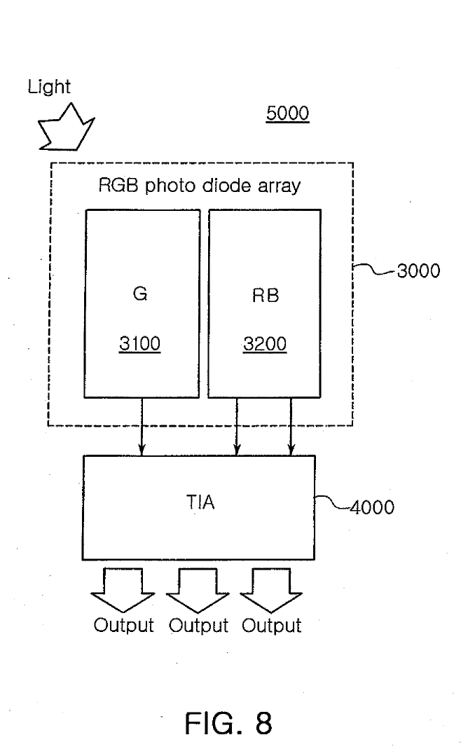

FIG. 8 is a block diagram illustrating a photodiode array of an optical sensor 5000 according to another embodiment of the invention, in which only a green light filter is adopted. Referring to FIG. 8, the optical sensor 5000 includes a photodiode array 3000 and a TIA 4000. The photodiode array 300 has at least two photodiode devices (first and second photodiode devices), which have a “n-p-i-n” structure according to the above-stated embodiment.

The photodiode array 3000 includes a first photodetector 3100 having a green light filter and a first photodiode device and a second photodetector 3200 having a second photodiode device without a filter. To enhance output, a plurality of photodiode devices can be used in a single photodetector 3100 or 3200. Upon having passed through the green light filter of the first photodetector 3100, green light is detected at a high efficiency by the first photodiode device below the green light filter.

The second photodetector 3200 does not include a color filter that allows the passage of specific wavelength visible light. However, the photodiode device in the second photodetector 3200 has a “n-p-i-n” double junction structure of the invention, and thus can detect a long wavelength of visible light and a short wavelength of visible light discriminatively from each other. That is, when light is emitted onto the second photodetector 3200, the short wavelength of visible light (blue light) is detected by the shallow p-n junction diode of the second photodiode device. In addition, of light incident onto the second photodetector 3200, the long wavelength of visible light (red light and green light) is detected by the deep pin junction diode of the second photodiode device, separately from the short wavelength of visible light.

Moreover, since green light can be selectively detected by the first photodetector 3100 having a green light filter, green light and red light in a long wavelength range can be detected discriminatively from each other. That is, when the amount of green visible light detected by the first photodetector 3100 is subtracted from the amount of the long wavelength of visible light (green and red visible lights) detected by the pin junction diode, the amount of red visible light out of the long wavelength of visible light detected by the second photodetector 3200 can be acquired.

As a result, red light and blue light are detected at a high efficiency respectively by the pin junction diode and the p-n junction diode of the second photodiode device in the second photodetector 3200. In addition, green light is detected at a high efficiency by the first photodiode device (in particular, the pin junction diode of the first photodiode device) of the first photodetector 3100. According to this embodiment, since red, green and blue wavelengths of light can be detected respectively with two photodiode devices, the occupation area of the photodiode array 3000 can be reduced significantly. This as a result can lead to high-density pixels and the miniaturization of an optical sensor device.

A double junction photodiode having a “p-n-i-p” structure can be produced by reversing the conductivity type of the semiconductor substrate and the semiconductor layers (or regions) of the above-stated embodiments. That is, a photodiode device capable of selectively detecting light at a high efficiency can be realized by replacing the p-type semiconductor substrate 101 with an n-type semiconductor substrate while reversing the conductivity type of the epitaxial layers 102 and 103, the well layer 104, the diffused region 116 and the buried region 106.

While the present invention has been described with reference to the particular illustrative embodiments and the accompanying drawings, it is not to be limited thereto but will be defined by the appended claims. It is to be appreciated that those skilled in the art can substitute, change or modify the embodiments into various forms without departing from the scope and spirit of the present invention.

According to certain embodiments of the invention as set forth above, a shallow p-n junction diode and a deep pin junction diode can be integrated in a single semiconductor substrate in order to detect short and long wavelengths of visible light discriminatively from each other at a high efficiency.

Furthermore, such a photodiode device can be applied to a photodiode array for an optical sensor to enhance the photosensitivity and optical output of the photodiode array. This also can reduce the occupation area of the array, thereby leading to high-density pixels and the miniaturization of optical sensor devices.

What is claimed is:

1. A photodiode device comprising:
a first conductivity type semiconductor substrate;
a second conductivity type buried layer, an intrinsic semiconductor layer and a first conductivity type semiconductor layer formed on the semiconductor substrate in their order; and
a second conductivity type well layer formed on the first conductivity type semiconductor layer,
wherein the second conductivity type buried layer, the intrinsic semiconductor layer and the first conductivity type semiconductor layer form a pin junction diode for detecting the long wavelength of visible light, and the first conductivity type semiconductor layer and the second conductivity type well layer form a p-n junction diode for detecting a short wavelength of light.

2. The photodiode device according to claim 1, wherein the first conductivity type is p-type, and the second conductivity type is n-type.

3. The photodiode device according to claim 1, wherein each of the first intrinsic semiconductor layer and the first conductivity type semiconductor layer is an epitaxial layer.

4. The photodiode device according to claim 1, wherein the semiconductor substrate comprises a Si substrate, and the semiconductor layers are made of a Si semiconductor.

5. The photodiode device according to claim 1, further comprising a second conductivity type vertical buried region extending through the first conductivity type semiconductor layer and the intrinsic semiconductor layer to the second conductivity type buried layer to provide a contact toward the second buried layer.

6. The photodiode device according to claim 1, wherein the second conductivity type well layer has a junction depth ranging from 0.1 μm to 0.2 μm.

7. The photodiode device according to claim 1, wherein an interface is provided between the first conductivity type semiconductor layer and the intrinsic semiconductor layer at a depth ranging from 1 μm to 1.5 μm.

8. The photodiode device according to claim 1, wherein an interface is provided between the intrinsic semiconductor layer and the second conductivity type semiconductor layer at a depth ranging from 5 μm to 7 μm.

9. The photodiode device according to claim 1, wherein an interface is provided between the second conductivity type buried layer and the semiconductor substrate at a depth ranging from 8 μm to 10 μm.

10. The photodiode device according to claim 1, wherein the second conductivity type well layer has a doping concentration ranging from 1×10¹⁹ cm⁻³ to 3×10¹⁹ cm⁻³.

11. The photodiode device according to claim 1, wherein the first conductivity type semiconductor layer has a doping concentration ranging from 5×10¹⁶ cm⁻³ to 5×10¹⁷ cm⁻³.

12. The photodiode device according to claim 1, wherein the intrinsic semiconductor layer has a doping concentration ranging from 1×10¹³ cm⁻³ to 1×10¹⁴ cm⁻³.

13. The photodiode device according to claim 1, wherein the second conductivity type buried layer has a doping concentration ranging from 1×10¹⁸ cm⁻³ to 3×10¹⁸ cm⁻³.

14. The photodiode device according to claim 1, wherein the semiconductor substrate has a doping concentration ranging from 1×10¹⁵ cm⁻³ to 1×10¹⁶ cm⁻³.

15. A photodiode array comprising:
at least one color filter; and
at least two photodiode devices,
wherein each of the photodiode devices comprises:
a first conductivity type semiconductor substrate;
a second conductivity type buried layer, an intrinsic semiconductor layer and a first conductivity type semiconductor layer formed on the semiconductor substrate in their order; and
a second conductivity type well layer formed on the first conductivity type semiconductor layer,
wherein the second conductivity type buried layer, the intrinsic semiconductor layer and the first conductivity type semiconductor layer form a pin junction diode for detecting the long wavelength of visible light, and the first conductivity type semiconductor layer and the second conductivity type well layer form a p-n junction diode for detecting a short wavelength of light.

16. The photodiode array according to claim 15, wherein the color filter includes a red light filter, a green light filter and a blue light filter,
wherein the photodiode devices include first to third photodiode devices, and
wherein the red light filter and the first photodiode device form a first photodetector, the green light filter and the second photodiode device form a second photodetector, and the blue light filter and the third photodiode device form a third photodetector.

17. The photodiode array according to claim 15, wherein the color filter includes a green light filter,
wherein the photodiode devices include first and second photodiode devices,
wherein the green light filter and the first photodiode device form a first photodetector for detecting green light, and
wherein the second photodiode device forms a second photodetector for detecting red and blue light without a color filter.
